(19) United States
(12) Patent Application Publication
(10) Pub. No.: US 2026/0058434 A1
(43) Pub. Date: Feb. 26, 2026

(54) SEMICONDUCTOR LASER LIGHT SOURCE DEVICE

(71) Applicant: Mitsubishi Electric Corporation, Tokyo (JP)

(72) Inventor: Seiji NAKANO, Tokyo (JP)

(73) Assignee: Mitsubishi Electric Corporation, Tokyo (JP)

(21) Appl. No.: 19/103,083

(22) PCT Filed: Oct. 21, 2022
(86) PCT No.: PCT/JP2022/039331

§ 371 Date: Feb. 11, 2025

(51) Int. Cl. H01S 5/0231; H01S 5/02315; H01S 5/02345; H01S 5/06

(52) U.S. Cl. CPC H01S 5/0231; H01S 5/02315; H01S 5/02345; H01S 5/0612

(57) ABSTRACT

A semiconductor laser light source device includes: a metal stem (1); a temperature control module (3) fixed to a front surface of the metal stem (1); a first support block (4) fixed to the temperature control module (3); a first dielectric substrate (5) having a back surface fixed to the first support block (4) and a front surface to which a semiconductor optical modulation element (6) is fixed and on which a first ground electrode pattern (5a) is formed; a second support block (9) fixed to the front surface of the metal stem (1); and a second dielectric substrate (10) fixed to the second support block (9) and having a front surface on which a second ground electrode pattern (10a) is formed. The second dielectric substrate (10) has a side surface located on the first dielectric substrate (5) side, the side surface having a region in which a metal film (13) electrically connected to the second ground electrode pattern (10a) is formed, the region having a length that is at least equal to or larger than half a length of the side surface.

### TECHNICAL FIELD

The present disclosure relates to a semiconductor laser light source device.

### BACKGROUND ART

SNS, video sharing services, and the like have been progressively spreading on a worldwide scale, and data transmission capacities have been increased in an accelerated manner. In order to achieve transmission of signals at higher speeds with larger capacities in limited installation spaces, speed increase and downsizing of semiconductor laser light source devices that generate optical signals for transmission have been progressing.

There is a semiconductor laser light source device mounted with a semiconductor optical modulation element that generates laser light modulated as an optical signal. As a structure of the semiconductor laser light source device, a transistor-outlined CAN (TO-CAN) structure that can be manufactured at low cost is generally employed. Patent Document 1 discloses a semiconductor laser light source device including a metal stem having a flat surface on which a temperature control module, first and second support blocks, first and second dielectric substrates, and the like are mounted.

Inputting of a high-frequency signal to a semiconductor optical modulation element is performed via the second dielectric substrate, electrically conductive wires, and the first dielectric substrate from a lead pin penetrating the metal stem. Therefore, a ground of the first dielectric substrate and a ground of the second dielectric substrate are desirably at the same potential.

CITATION LIST

### Patent Document

Patent Document 1: Japanese Laid-Open Patent Publication No. 2022-88061

### SUMMARY OF THE INVENTION

### Problem to Be Solved by the Invention

In the configuration described in Patent Document 1, a castellation is formed in the second dielectric substrate in order to electrically connect the second support block and a ground electrode formed on a main surface of the second dielectric substrate, and the connection therebetween is established via the castellation. However, the configuration described in Patent Document 1 has problems in that a conduction means such as the castellation or a penetration via is highly difficult to make, requires high cost, and leads to decrease in the degree of freedom in mounting an electrically conductive wire.

The configuration described in Patent Document 1 further has problems in that: the castellation or the penetration via makes it difficult to stabilize a ground level; and, depending on the arrangement position of the castellation or the penetration via, the distance from the stem is elongated to weaken the ground so that a pass characteristic for a high-frequency signal easily deteriorates.

The present disclosure has been made to solve the above problems, and an object of the present disclosure is to provide a semiconductor laser light source device in which a favorable pass characteristic for a high-frequency signal is obtained with a simple configuration.

### Means to Solve the Problem

A semiconductor laser light source device according to the present disclosure includes: a metal stem having a plurality of lead pins fixed by penetrating a back surface and a front surface of the metal stem; a temperature control module fixed to the front surface of the metal stem; a first support block made of a metal and fixed to a surface, of the temperature control module, on an opposite side to a surface thereof fixed to the metal stem, the first support block having a first surface perpendicular to the front surface of the metal stem; a first dielectric substrate having a back surface fixed to the first surface of the first support block, the first dielectric substrate having a front surface to which a semiconductor optical modulation element is fixed and on which a first ground electrode pattern and a first signal line having one end electrically connected to the semiconductor optical modulation element are formed; a second support block made of a metal and fixed to the front surface of the metal stem, the second support block having a second surface parallel to the first surface of the first support block; and a second dielectric substrate having a back surface fixed to the second surface of the second support block, the second dielectric substrate having a front surface on which a second signal line and a second ground electrode pattern electrically connected to the first ground electrode pattern are formed, the second signal line having one end electrically connected to one lead pin among the lead pins, the second signal line having another end electrically connected to another end of the first signal line. The second dielectric substrate has a side surface located on the first dielectric substrate side, the side surface having a region in which a first metal film electrically connected to the second ground electrode pattern is formed, the region having a length that is at least equal to or larger than half a length of the side surface.

### EFFECT OF THE INVENTION

The present disclosure makes it possible to provide a semiconductor laser light source device in which a favorable pass characteristic for a high-frequency signal is obtained with a simple configuration.

### BRIEF DESCRIPTION OF THE DRAWINGS

FIG. 1 is a perspective view schematically showing a configuration of a semiconductor laser light source device according to embodiment 1.

FIG. 2 is a perspective view showing the appearance of the semiconductor laser light source device according to embodiment 1.

FIG. 3 shows pass characteristics, for a high-frequency signal, of the semiconductor laser light source device according to embodiment 1 through comparison with a pass characteristic of the conventional semiconductor laser light source device.

FIG. 4 is an enlarged perspective view showing a main section of a semiconductor laser light source device according to embodiment 2.

FIG. 5 shows a pass characteristic, for a high-frequency signal, of the semiconductor laser light source device according to embodiment 2 through comparison with the pass characteristic of the conventional semiconductor laser light source device.

FIG. 6 is a perspective view of a second dielectric substrate in a semiconductor laser light source device according to embodiment 3.

FIG. 7 shows a pass characteristic, for a high-frequency signal, of the semiconductor laser light source device according to embodiment 3 through comparison with the pass characteristic of the semiconductor laser light source device according to embodiment 1.

FIG. 8 is an enlarged perspective view showing a main section of a semiconductor laser light source device according to embodiment 4.

FIG. 9 shows a pass characteristic, for a high-frequency signal, of the semiconductor laser light source device according to embodiment 4 through comparison with the pass characteristic of the semiconductor laser light source device according to embodiment 1.

### DESCRIPTION OF EMBODIMENTS

Hereinafter, embodiments will be described with reference to the drawings. The drawings are schematic illustrations, and the mutual relationship between the sizes and the positions of images shown in the respective different drawings is not necessarily accurately rendered and may be changed as appropriate.

### Embodiment 1

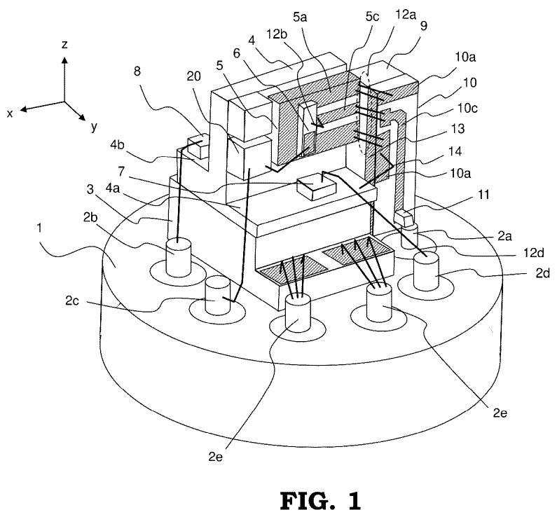

FIG. 1 is a perspective view schematically showing a configuration of a semiconductor laser light source device according to embodiment 1. FIG. 1 shows an x axis, a y axis, and a z axis indicating three-dimensional directions. As shown in FIG. 1, the semiconductor laser light source device includes a metal stem 1 having a plurality of lead pins 2a, 2b, 2c, 2d, and 2e penetrating a front surface and a back surface of the metal stem 1. On the front surface side of the metal stem 1, a semiconductor optical modulation element 6 and a member for driving the semiconductor optical modulation element 6 are mounted. The plurality of lead pins 2a, 2b, 2c, 2d, and 2e are used for electrically connecting the outside and respective electrical parts mounted on the metal stem 1. The semiconductor optical modulation element 6 is mounted on a front surface of a first dielectric substrate 5. The first dielectric substrate 5 is fixed to a front surface (also referred to as “first surface”), of a first support block 4, extending to be perpendicular to the front surface of the metal stem 1. The first support block 4 is fixed to a temperature control module 3 fixed to the metal stem 1. The first support block 4 has, on a side thereof fixed to the temperature control module 3, a first base portion 4a and a second base portion 4b which are formed to extend in a direction parallel to a surface, of the temperature control module 3, to which the first support block is fixed. The first base portion 4a and the second base portion 4b extend in mutually opposite directions. A light-receiving element 7 for receiving light emitted from a rear surface of the semiconductor optical modulation element 6 is fixed to the first base portion 4a formed on the side on which the first dielectric substrate 5 is mounted. A temperature sensor 8 for monitoring a temperature is fixed to the second base portion 4b extending in a direction opposite to the direction in which the first base portion 4a extends.

Furthermore, a second support block 9 is fixed to the front surface of the metal stem 1. The second support block 9 has a front surface (also referred to as “second surface”) which extends in a direction perpendicular to the front surface of the metal stem 1 and to which a second dielectric substrate 10 is joined. The first surface of the first support block 4 and the second surface of the second support block 9 are in such a positional relationship as to be parallel to each other. A second ground electrode pattern 10a and a second signal line 10c are formed on a front surface (the surface on the opposite side to the surface (back surface) joined to the second support block 9) of the second dielectric substrate 10. The second signal line 10c has one end electrically connected via an electrical conductor 11 such as a solder to one of the lead pins which is the lead pin 2a. The second signal line 10c has another end electrically connected via electrically conductive wires 12a to one end of a first signal line 5c formed on the front surface of the first dielectric substrate 5. The first signal line 5c has another end electrically connected via an electrically conductive wire 12b to a modulator of the semiconductor optical modulation element 6. The second ground electrode pattern 10a is electrically connected via electrically conductive wires 12a to a first ground electrode pattern 5a formed on the front surface of the first dielectric substrate 5. Furthermore, in order to electrically connect the second ground electrode pattern 10a and the second support block 9, the second dielectric substrate 10 has a side surface located on the first dielectric substrate 5 side, the side surface having a region in which a first metal film 13 electrically connected to the second ground electrode pattern 10a is formed, the region having a length that is at least equal to or larger than half a length of the side surface. In addition, the second ground electrode pattern 10a and the first base portion 4a of the first support block 4 are electrically connected via an electrically conductive wire 14.

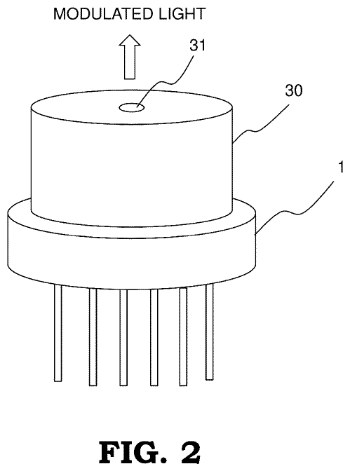

FIG. 2 is a perspective view showing the appearance of the semiconductor laser light source device according to embodiment 1 as a product. As shown in FIG. 2, the semiconductor laser light source device is, on the metal stem 1 side thereof on which each member is mounted, covered with an airtight sealing cap 30, and an internal space which is formed by the airtight sealing cap 30 and the metal stem 1 and in which each member is mounted is sealed in an airtight manner. In this configuration, modulated light obtained through modulation is radiated from an airtight window 31 provided to the airtight sealing cap 30. Meanwhile, FIG. 1 is a perspective view in a state where the airtight sealing cap 30 is detached so that the inside is exposed.

The metal stem 1 is formed in the shape of a substantially circular plate and is, for example, a metal-material stem base obtained by plating, with Au or the like, a front surface of a material having a high thermal conductivity such as Cu. The metal stem 1 serves to fix the second support block 9, the temperature control module 3, and the like and release heat absorbed by the temperature control module 3 to a cooling member (not shown) provided on the negative side in the z direction (back surface side) of the metal stem 1.

In order to fix each of the lead pins to the metal stem 1, glass is generally used for a penetration hole provided in the metal stem 1. In particular, for the lead pin 2a electrically joined to the second signal line 10c of the second dielectric substrate 10, glass as a material having a low permittivity is used so as to obtain the same impedance as that of a signal generator. When inequality in impedance occurs, the frequency response characteristic deteriorates owing to multiple reflection of a signal, whereby high-speed modulation becomes difficult.

A compression method or a matching method is generally employed in order to fix the lead pin at each of lead portions to the metal stem 1 through sealing with the glass. In these methods, it is important to set the pressures of the respective lead portions to be equal to one another at the time of sealing in order to maintain airtightness, and thus the lead portions are desirably arranged such that the distances thereto from the outer circumference of the metal stem 1 are equal to one another, i.e., are desirably arranged at positions that form a circular pattern. In addition, since an excessively short interval between adjacent ones of the lead portions leads to deterioration of sealing performance, a certain extent of distance is necessary therebetween.

As a joining material for joining the metal stem 1 and the temperature control module 3, for example, SnAgCu solder, AuSn solder, an electrically conductive adhesive, or the like is used. The temperature control module 3 is formed by, for example, interposing a plurality of blocks made from a material such as BiTe between two substrates made from a material such as AlN and serves to dissipate heat received from the semiconductor optical modulation element 6 mounted on the substrate on the upper surface side, from the lower substrate to the metal stem 1 side.

The oscillation wavelength of laser light changes in association with change in the temperature of the semiconductor optical modulation element 6, and thus said temperature needs to be kept unchanged. The temperature control module 3 is mounted in consideration of this need. Consequently, when the temperature of the semiconductor optical modulation element 6 increases, cooling is performed, and in contrast, when said temperature decreases, heat is applied, whereby the temperature of the semiconductor optical modulation element 6 can be kept unchanged.

The first dielectric substrate 5 is formed in the shape of a plate and is, for example, obtained by plating with Au and metallizing, a front surface of a ceramic material such as aluminum nitride (AlN). Ordinarily, a back surface ground electrode is formed on a back surface (the surface fixed to the first support block 4) of the first dielectric substrate. The first dielectric substrate 5 serves to fix the semiconductor optical modulation element 6 and release heat generated by the semiconductor optical modulation element 6 to the cooling member on the back surface side of the metal stem 1 via the first support block 4 and the temperature control module 3. In general, the first dielectric substrate 5 has an electric insulation function and a heat transmission function.

The first signal line 5c and the first ground electrode pattern 5a are formed on the front surface of the first dielectric substrate 5. The first signal line 5c has one end electrically connected via the wire 12b to the modulator of the semiconductor optical modulation element 6. Another end of the first signal line 5c and the first ground electrode pattern 5a are electrically connected via the different electrically conductive wires 12a to the second signal line 10c and the second ground electrode pattern 10a formed on the front surface of the second dielectric substrate 10, respectively. Through these connections, a to-be-modulated high-frequency signal inputted from the one lead pin 2a is inputted to the modulator of the semiconductor optical modulation element 6, and modulated light at a high speed is generated from the semiconductor optical modulation element 6.

The first support block 4 is, for example, a metal-material block obtained by plating, with Au or the like, a front surface of a material having a high thermal conductivity such as Cu, has the first base portion 4a and the second base portion 4b, and is joined to the temperature control module 3 via a solder or the like. The first support block 4 serves to fix the first dielectric substrate 5 and the like and transmit heat generated by the semiconductor optical modulation element 6 to the temperature control module 3 side.

The semiconductor optical modulation element 6 is, for example, a modulator-integrated laser diode (EAM-LD) obtained by monolithically integrating an electro-absorption optical modulator in which InGaAsP-based quantum well absorption layers and a distributed-feedback laser diode are used. From a light emitting point on the semiconductor optical modulation element 6, laser light is radiated along an optical axis that is perpendicular to a chip end surface and that is parallel to a chip main surface.

In order to obtain a higher optical output, an optical amplifier (semiconductor optical amplifier (SOA)) may be further integrated in the direction of emission from the semiconductor optical modulation element 6.

A method for supplying power to the distributed-feedback laser diode may include establishing direct connection from the lead pin 2c via electrically conductive wires or may include, as shown in FIG. 1, establishing connection by passage through a capacitor 20.

In order to obtain a maximum voltage amplitude from the signal generator, a matching resistor may be connected on the first dielectric substrate 5 in parallel to the semiconductor optical modulation element 6.

The second support block 9 is, for example, a metal-material block obtained by plating, with Au or the like, a front surface of a material having a high thermal conductivity such as Cu, is joined to the front surface of the metal stem 1 via a solder or the like, and serves to fix the second dielectric substrate 10 and the like. The second support block 9 may be formed to be integrated with the metal stem 1 or may be mounted on the metal stem 1 as a separate part.

The second dielectric substrate 10 is formed in the shape of a plate and is, for example, obtained by metallizing and plating, with Au, a front surface of a ceramic material such as aluminum nitride (AlN). Ordinarily, a back surface ground electrode is formed on a back surface (the surface fixed to the second support block 9) of the second dielectric substrate. The second signal line 10c is formed on the front surface of the second dielectric substrate 10, has one end electrically connected to the first signal line 5c of the first dielectric substrate 5, and has another end electrically connected to the lead pin 2a via the electrical conductor 11 such as a solder or an electrically conductive wire. The second ground electrode pattern 10a is formed on the front surface of the second dielectric substrate 10 and is electrically connected to the first dielectric substrate 5 via the corresponding electrically conductive wires 12a.

The first metal film 13 connecting the back surface ground electrode and the second ground electrode pattern 10a of the second dielectric substrate 10 is formed on the side surface, of the second dielectric substrate 10, on the positive side in the x-axis direction, i.e., the side on which the first dielectric substrate 5 is located. The second ground electrode pattern 10a and the second support block 9 are electrically connected via the first metal film 13. The first metal film 13 is formed in a region having a length that is at least larger than half the length of the side surface, of the second dielectric substrate 10, on which the first metal film 13 is formed.

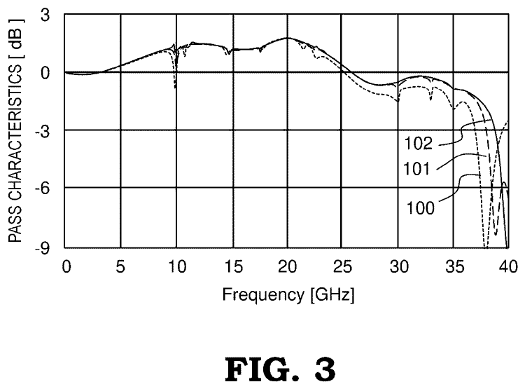

In the configuration described in Patent Document 1, a castellation or a penetration via is formed in a dielectric substrate corresponding to the second dielectric substrate 10, and a ground electrode pattern formed on the front surface and a support block corresponding to the second support block 9 are electrically connected. However, in the configuration described in Patent Document 1, it is difficult to stabilize the ground level, and, depending on the arrangement position, the distance from the stem is elongated to weaken the ground. FIG. 3 shows high-frequency pass characteristics from the lead pin 2a to the semiconductor optical modulation element 6. A pass characteristic obtained in a configuration in which the second dielectric substrate 10 and the second support block 9 are connected via a castellation or a penetration via as in the configuration described in Patent Document 1, is as indicated by a broken line 100 in FIG. 3. The pass characteristic sustains a dip of about 3 dB due to influence of signal resonance at 10 GHz and is significantly attenuated owing to influence of signal reflection in a band of 20 GHz or higher. Meanwhile, in the present embodiment, neither a castellation nor a penetration via is provided, and the second ground electrode pattern 10a and the second support block 9 are electrically connected via the first metal film 13, whereby the ground is stabilized and intensified. Consequently, a pass characteristic indicated by a broken line 101 in FIG. 3 is obtained. However, the pass characteristic indicated by the broken line 101 in FIG. 3 is a pass characteristic obtained in a state where the electrically conductive wire 14 is absent. Thus, it is found that, in the configuration according to the present embodiment 1 in the state where the electrically conductive wire 14 is absent, the dip due to influence of signal resonance at 10 GHz is suppressed, the characteristic is improved by about 1 dB in the band of 20 GHz or higher owing to suppression of signal reflection, and the band of cutoff frequencies is widened by about 2 GHz. In this manner, owing to the enhancement of the flatness of the pass characteristic (i.e., S21 among S-parameters) and the widening of the band of cutoff frequencies, jitter components decrease in an optical waveform, whereby a favorable eye pattern is obtained.

In addition, when a castellation or a penetration via is formed in the second dielectric substrate 10 as in the configuration described in Patent Document 1, no electrically conductive wire can be bonded to the portion at which the castellation or the penetration via has been formed, whereby the degree of freedom in mounting an electrically conductive wire decreases, and furthermore, difficulty in and cost for manufacturing become high. Considering this, the first metal film 13 is formed on the side surface of the second dielectric substrate 10. Consequently, the need for a castellation or a penetration via can be eliminated, and the degree of freedom in mounting an electrically conductive wire is improved.

Electrical connection between the second ground electrode pattern 10a and the first support block 4 via an electrically conductive wire leads to intensification of the ground and improvement in a high-frequency characteristic. However, when the position of bonding of the electrically conductive wire to the first support block 4 is present on the mounting surface for the first dielectric substrate 5, there is a concern that a sticking-out portion of a joining material on the back surface of the first dielectric substrate 5 interferes with the electrically conductive wire so that the electrically conductive wire peels off. Furthermore, a mounting jig interferes with the electrically conductive wire at the time of mounting the first dielectric substrate 5. Thus, the presence of said position on the mounting surface is not desirable. Considering this, as shown in FIG. 1, the first base portion 4a is formed as a portion of the first support block 4, and the electrically conductive wire 14 is bonded to the first base portion 4a. Consequently, it becomes possible to avoid interference of the joining material and the jig while obtaining a ground-intensifying characteristic equivalent to that obtained when the electrically conductive wire is bonded to the mounting surface for the first dielectric substrate 5.

Connection between the second ground electrode pattern 10a and the first base portion 4a via the electrically conductive wire 14 leads to obtainment of a pass characteristic indicated by a solid line 102 in FIG. 3. Thus, it is found that, as compared to the broken line 101 indicating the pass characteristic in the case where the electrically conductive wire 14 is not mounted, the dip at 10 GHz is further suppressed and the band of cutoff frequencies is widened by about 1 GHz.

The light-receiving element 7 for converting an optical signal into an electric signal (performing O/E conversion) is mounted on the first base portion 4a and makes it possible to monitor the intensity of light from the rear surface of the semiconductor optical modulation element 6. The received optical signal is converted into an electric signal, and the electric signal is transmitted to the lead pin 2d via an electrically conductive wire 12d connected to the light-receiving element 7. Since the intensity of the light can be monitored, drive current for the distributed-feedback laser diode can be controlled such that the optical output is kept unchanged.

In addition, the second base portion 4b may be formed as a portion of the first support block 4, and the thermistor 8 or the like may be mounted on the second base portion 4b. The thermistor 8 is present in order to indirectly observe the temperature of the semiconductor optical modulation element 6 and feeds back the observed temperature to the temperature control module 3. Consequently, when the temperature of the semiconductor optical modulation element 6 is higher than a target value, cooling is performed, and in contrast, when said temperature is low, heat generation is caused, whereby the temperature of the semiconductor optical modulation element 6 can be stabilized.

### Embodiment 2

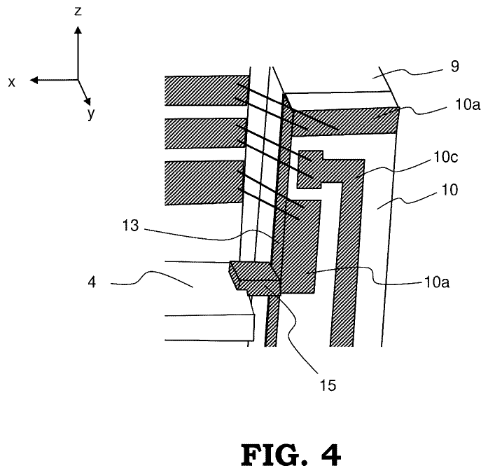

FIG. 4 is an enlarged view of a main section of a semiconductor laser light source device according to embodiment 2. As shown in FIG. 4, an electrically conductive adhesive 15 is used as a means for connecting the first support block 4 and the first metal film 13 formed on the side surface.

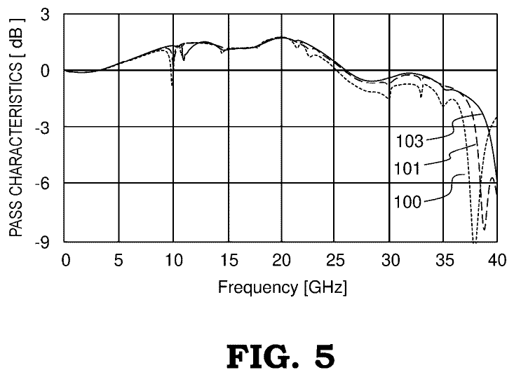

A high-frequency pass characteristic obtained in the configuration in FIG. 4 is a characteristic indicated by a solid line 103 in FIG. 5. According to the configuration in FIG. 4, it is found that the influence of the resonance at 10 GHz is suppressed and the band of cutoff frequencies is widened in the same manner as the pass characteristic which is indicated by the solid line 102 in FIG. 3 and which is obtained in the configuration shown in FIG. 1 in which the second ground electrode pattern 10a and the first support block 4 are electrically connected via the electrically conductive wire 14. Furthermore, it is found that, in the pass characteristic indicated by the solid line 103 in FIG. 5, the band of cutoff frequencies is further widened by about 0.5 GHz as compared to the pass characteristic indicated by the solid line 102 in FIG. 3.

### Embodiment 3

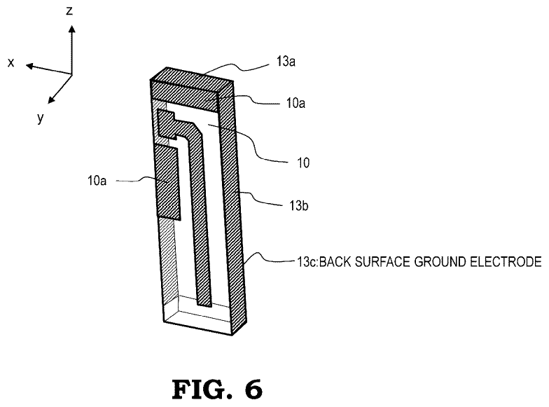

FIG. 6 is a perspective view of a second dielectric substrate 10 in a semiconductor laser light source device according to embodiment 3. As shown in FIG. 6, a second metal film 13a and a third metal film 13b which are connected to a back surface ground electrode 13c formed on the back surface of the second dielectric substrate 10 are respectively formed on a side surface on the positive side in the z-axis direction (the opposite side to the front surface of the metal stem 1) of the second dielectric substrate 10 and a side surface on the negative side in the x-axis direction (the opposite side to the side on which the first dielectric substrate 5 is located) of the second dielectric substrate 10. The second ground electrode pattern 10a and the second support block 9 are electrically connected via the second metal film 13a and the third metal film 13b.

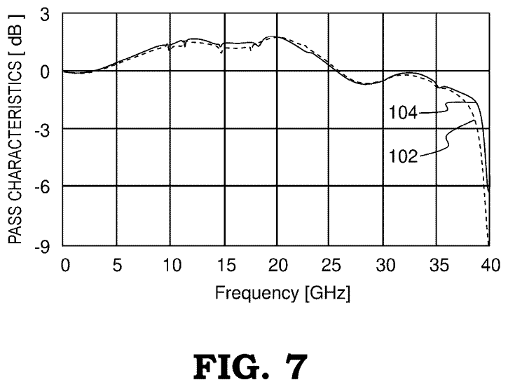

Consequently, the ground is further intensified as compared to the configuration of embodiment 1 shown in FIG. 1, and, as in a pass characteristic indicated by a solid line 104 in FIG. 7, suppression of reflection at around 15 GHz and widening of the band of cutoff frequencies are observed as compared to the pass characteristic 102 (the pass characteristic 102 indicated by a solid line in FIG. 3 is indicated by a broken line in FIG. 7) which is indicated by the broken line and which is obtained in the configuration of embodiment 1.

### Embodiment 4

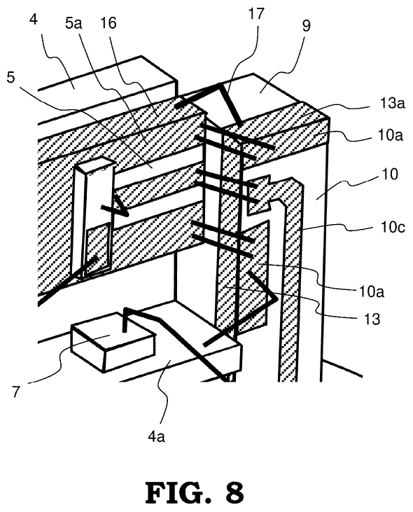

FIG. 8 is an enlarged view of a main section of a semiconductor laser light source device according to embodiment 4. As shown in FIG. 8, a fourth metal film 16 connecting the first ground electrode pattern 5a and the back surface ground electrode formed on the back surface of the first dielectric substrate 5 is formed on a side surface (located on the opposite side to the front surface of the metal stem) on the positive side in the z-axis direction of the first dielectric substrate 5 and establishes electrical conduction between the first support block 4 and the first ground electrode pattern 5a formed on the front surface of the first dielectric substrate 5.

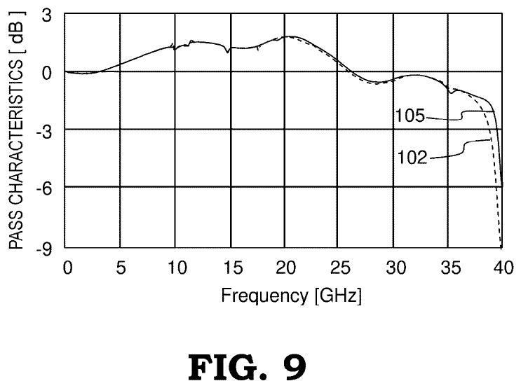

The fourth metal film 16 and the second metal film 13a on the corresponding side surface of the second dielectric substrate 10 are electrically connected via an electrically conductive wire 17, and the ground of the first dielectric substrate 5 is further intensified. Consequently, the ground is further intensified as compared to the configuration of embodiment 1 as in a pass characteristic indicated by a solid line 105 in FIG. 9, and widening of the band of cutoff frequencies is observed as compared to the pass characteristic 102 (the pass characteristic 102 indicated by a solid line in FIG. 3 is indicated by a broken line in FIG. 8) which is indicated by the broken line and which is obtained in the configuration of embodiment 1.

The advantageous effects of the semiconductor laser light source devices according to the respective embodiments of the present disclosure are summarized as follows. Although no electrically conductive wire can be bonded to the conventionally provided castellation or penetration via portion, formation of a metal film on a side surface of a dielectric substrate enables bonding also to a place in which bonding has not been able to be performed conventionally, whereby the degree of freedom in mounting is improved. The configuration in which the metal film is formed on the side surface of the dielectric substrate makes it easier to perform manufacturing and requires lower cost than the configuration provided with the castellation or the penetration via. The formation of the metal film on the side surface of the dielectric substrate leads to stabilization and intensification of the ground level and improvement in the high-frequency pass characteristic as compared to the case of the castellation or the penetration via.

When the first support block 4 and the second ground electrode pattern 10a formed on the front surface of the second dielectric substrate 10 are connected via an electrically conductive wire, the ground is intensified, and the high-frequency characteristic is improved. In this case, when the position of bonding to the first support block 4 is present on a surface on which the first dielectric substrate 5 is mounted, there is a concern that, at the time of joining the first dielectric substrate 5 to the first support block 4, an expanded portion of a joining material on the back surface comes into contact with the bonded portion so that the electrically conductive wire peels off. Considering this, the position of bonding to the first support block 4 is desirably present on the front surface of the first base portion 4a on which the light-receiving element 7 is mounted and which is formed as a portion of the first support block.

When the first support block 4 and the first metal film 13 formed on the corresponding side surface of the second dielectric substrate 10 are connected by the electrically conductive adhesive 15, the ground is intensified and the high-frequency characteristic is improved.

When metal films are formed on both left and right side surfaces and the upper side surface of the second dielectric substrate 10, and furthermore, connection from the second metal film 13a on the upper side surface of the second dielectric substrate 10 to the fourth metal film 16 on the upper side surface of the first dielectric substrate 5 is established via the electrically conductive wire 17, the ground is further intensified and the high-frequency pass characteristic is improved.

Although various exemplary embodiments and examples are described in the present application, various features, aspects, and functions described in one or more embodiments are not inherent in a particular embodiment, and can be applicable alone or in their various combinations to each embodiment. Accordingly, countless variations that are not illustrated are envisaged within the scope of the art disclosed herein. For example, the case where at least one component is modified, added or omitted, and the case where at least one component is extracted and combined with a component in another embodiment are included.

### DESCRIPTION OF THE REFERENCE CHARACTERS

1 metal stem
2a, 2b, 2c, 2d, 2e lead pin
3 temperature control module
4 first support block
4a first base portion
4b second base portion
5 first dielectric substrate
5a first ground electrode pattern
5c first signal line
6 semiconductor optical modulation element
9 second support block
10 second dielectric substrate
10a second ground electrode pattern
10c second signal line
13 first metal film
13a second metal film
13b third metal film
15 electrically conductive adhesive
16 fourth metal film
17 electrically conductive wire
30 airtight sealing cap

1. A semiconductor laser light source device comprising:
a metal stem having a plurality of lead pins fixed by penetrating a back surface and a front surface of the metal stem;
a temperature control module fixed to the front surface of the metal stem;
a first support block made of a metal and fixed to a surface, of the temperature control module, on an opposite side to a surface thereof fixed to the metal stem, the first support block having a first surface perpendicular to the front surface of the metal stem;
a first dielectric substrate having a back surface fixed to the first surface of the first support block, the first dielectric substrate having a front surface to which a semiconductor optical modulation element is fixed and on which a first ground electrode pattern and a first signal line having one end electrically connected to the semiconductor optical modulation element are formed;
a second support block made of a metal and fixed to the front surface of the metal stem, the second support block having a second surface parallel to the first surface of the first support block; and
a second dielectric substrate having a back surface fixed to the second surface of the second support block, the second dielectric substrate having a front surface on which a second signal line and a second ground electrode pattern electrically connected to the first ground electrode pattern are formed, the second signal line having one end electrically connected to one lead pin among the lead pins, the second signal line having another end electrically connected to another end of the first signal line, wherein
the second dielectric substrate has a side surface located on the first dielectric substrate side, the side surface having a region in which a first metal film electrically connected to the second ground electrode pattern is formed, the region having a length that is at least equal to or larger than half a length of the side surface and wherein
the first support block has, on a side thereof fixed to the temperature control module, a first base portion formed to extend from the first surface in a direction parallel to the surface, of the temperature control module, to which the first support block is fixed, and
the semiconductor laser light source device further comprises an electrically conductive wire electrically connecting the second ground electrode pattern and the first base portion.

2. (canceled)

3. A semiconductor laser light source device comprising:
a metal stem having a plurality of lead pins fixed by penetrating a back surface and a front surface of the metal stem;
a temperature control module fixed to the front surface of the metal stem;
a first support block made of a metal and fixed to a surface, of the temperature control module, on an opposite side to a surface thereof fixed to the metal stem, the first support block having a first surface perpendicular to the front surface of the metal stem;
a first dielectric substrate having a back surface fixed to the first surface of the first support block, the first dielectric substrate having a front surface to which a semiconductor optical modulation element is fixed and on which a first ground electrode pattern and a first signal line having one end electrically connected to the semiconductor optical modulation element are formed;
a second support block made of a metal and fixed to the front surface of the metal stem, the second support block having a second surface parallel to the first surface of the first support block; and
a second dielectric substrate having a back surface fixed to the second surface of the second support block, the second dielectric substrate having a front surface on which a second signal line and a second ground electrode pattern electrically connected to the first ground electrode pattern are formed, the second signal line having one end electrically connected to one lead pin among the lead pins, the second signal line having another end electrically connected to another end of the first signal line, wherein
the second dielectric substrate has a side surface located on the first dielectric substrate side, the side surface having a region in which a first metal film electrically connected to the second ground electrode pattern is formed, the region having a length that is at least equal to or larger than half a length of the side surface and wherein
the first support block has, on a side thereof fixed to the temperature control module, a first base portion formed to extend from the first surface in a direction parallel to the surface, of the temperature control module, to which the first support block is fixed, and
the first metal film and the first base portion are electrically connected via an electrically conductive adhesive.

4. The semiconductor laser light source device according to claim 1, wherein
the second dielectric substrate has
a side surface on an opposite side to the metal stem, said side surface on the opposite side having a region in which a second metal film is formed, the region having a length that is equal to or larger than half a length of said side surface on the opposite side, and
a side surface on an opposite side to the side surface on which the first metal film is formed, said side surface on the opposite side having a region in which a third metal film is formed, the region having a length that is equal to or larger than half a length of said side surface on the opposite side.

5. A semiconductor laser light source device comprising:
a metal stem having a plurality of lead pins fixed by penetrating a back surface and a front surface of the metal stem;
a temperature control module fixed to the front surface of the metal stem;
a first support block made of a metal and fixed to a surface, of the temperature control module, on an opposite side to a surface thereof fixed to the metal stem, the first support block having a first surface perpendicular to the front surface of the metal stem;
a first dielectric substrate having a back surface fixed to the first surface of the first support block, the first dielectric substrate having a front surface to which a semiconductor optical modulation element is fixed and on which a first ground electrode pattern and a first signal line having one end electrically connected to the semiconductor optical modulation element are formed;
a second support block made of a metal and fixed to the front surface of the metal stem, the second support block having a second surface parallel to the first surface of the first support block; and
a second dielectric substrate having a back surface fixed to the second surface of the second support block, the second dielectric substrate having a front surface on which a second signal line and a second ground electrode pattern electrically connected to the first ground electrode pattern are formed, the second signal line having one end electrically connected to one lead pin among the lead pins, the second signal line having another end electrically connected to another end of the first signal line, wherein
the second dielectric substrate has a side surface located on the first dielectric substrate side, the side surface having a region in which a first metal film electrically connected to the second ground electrode pattern is formed, the region having a length that is at least equal to or larger than half a length of the side surface,
the second dielectric substrate has
a side surface on an opposite side to the metal stem, said side surface on the opposite side having a region in which a second metal film is formed, the region having a length that is equal to or larger than half a length of said side surface on the opposite side, and
a side surface on an opposite side to the side surface on which the first metal film is formed, said side surface on the opposite side having a region in which a third metal film is formed, the region having a length that is equal to or larger than half a length of said side surface on the opposite side,
the first dielectric substrate has a side surface located on the opposite side to the metal stem, said side surface on the opposite side having a region in which a fourth metal film electrically connecting the first ground electrode pattern and the first support block is formed, the region having a length that is at least equal to or larger than half a length of said side surface on the opposite side, and
the second metal film and the fourth metal film are connected via an electrically conductive wire.

6. The semiconductor laser light source device according to claim 1, further comprising
an airtight sealing cap covering the front surface side of the metal stem.

7. The semiconductor laser light source device according to claim 4, wherein
the first dielectric substrate has a side surface located on the opposite side to the metal stem, said side surface on the opposite side having a region in which a fourth metal film electrically connecting the first ground electrode pattern and the first support block is formed, the region having a length that is at least equal to or larger than half a length of said side surface on the opposite side, and
the second metal film and the fourth metal film are connected via an electrically conductive wire.

8. The semiconductor laser light source device according to claim 3, wherein
the second dielectric substrate has
a side surface on an opposite side to the metal stem, said side surface on the opposite side having a region in which a second metal film is formed, the region having a length that is equal to or larger than half a length of said side surface on the opposite side, and
a side surface on an opposite side to the side surface on which the first metal film is formed, said side surface on the opposite side having a region in which a third metal film is formed, the region having a length that is equal to or larger than half a length of said side surface on the opposite side.

9. The semiconductor laser light source device according to claim 8 wherein
the first dielectric substrate has a side surface located on the opposite side to the metal stem, said side surface on the opposite side having a region in which a fourth metal film electrically connecting the first ground electrode pattern and the first support block is formed, the region having a length that is at least equal to or larger than half a length of said side surface on the opposite side, and
the second metal film and the fourth metal film are connected via an electrically conductive wire.

10. The semiconductor laser light source device according to claim 3, further comprising
an airtight sealing cap covering the front surface side of the metal stem.

11. The semiconductor laser light source device according to claim 5, further comprising
an airtight sealing cap covering the front surface side of the metal stem.
